(19) United States
(12) Patent Application Publication
(10) Pub. No.: US 2016/0172188 A1
(43) Pub. Date: Jun. 16, 2016

(54) RINSE SOLUTION FOR SILICA THIN FILM, METHOD OF PRODUCING SILICA THIN FILM, AND SILICA THIN FILM

(71) Applicant: SAMSUNG SDI CO., LTD., Yongin-si (KR)

(72) Inventors: Wan-Hee Lim, Suwon-si (KR); Il Jung, Suwon-si (KR); Sang-Ran Koh, Suwon-si (KR); Woo-Han Kim, Suwon-si (KR); Ha-Neul Kim, Suwon-si (KR); Hui-Chan Yun, Suwon-si (KR); Han-Song Lee, Suwon-si (KR)

(21) Appl. No.: 14/754,346

(22) Filed: Jun. 29, 2015

(30) Foreign Application Priority Data
Dec. 16, 2014 (KR) 10-2014-0181864
Jun. 4, 2015 (KR) 10-2015-0079441

(51) Int. Cl. H01L 21/02; C01B 21/087; C01B 33/12

(52) U.S. Cl. CPC H01L 21/02164; H01L 21/02282; H01L 21/02343; C01B 33/12; C01B 21/087

(57) ABSTRACT

A rinse solution for a silica thin film includes trimethylbenzene, diethylbenzene, indane, indene, tert-butyl toluene, methylnaphthalene, a mixture including an aromatic hydrocarbon having 12 or more carbon atoms, a mixture including an aliphatic hydrocarbon having 12 or more carbon atoms, a mixture including a hetero hydrocarbon compound including a phenyl group and an oxygen atom, or a combination thereof.

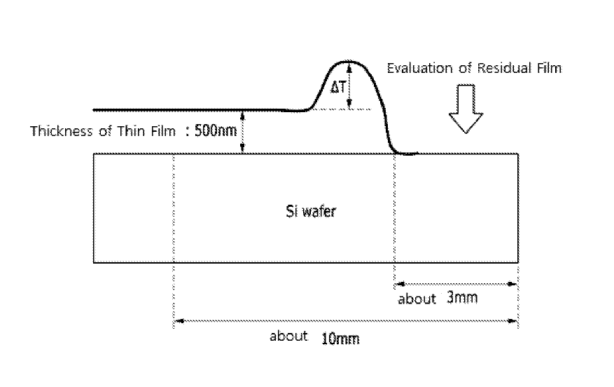

### CROSS-REFERENCE TO RELATED APPLICATION

This application claims priorities to and the benefits of Korean Patent Application No. 10-2014-0181864, filed in the Korean Intellectual Property Office on Dec. 16, 2014, and Korean Patent Application No. 10-2015-0079441, filed in the Korean Intellectual Property Office on Jun. 4, 2015, the entire contents of both are incorporated herein by reference.

### BACKGROUND

1. Field

This disclosure relates to a rinse solution for a silica thin film, a method of forming the silica thin film, and a silica thin film.

2. Description of the Related Art

Silica is utilized as a material coated on a substrate having a concavo-convex surface (e.g., a surface that is not flat), and is heated to gap-fill a groove thereon to planarize the surface. A silica thin film formed of such a silica material is widely utilized as, for example, an interlayer insulating layer, a planarization layer, a passivation film, a device insulation interlayer, or the like for a semiconductor device (such as an Large Scale Integration (LSI), a thin film transistor (TFT) liquid crystal display (LCD), or the like). For example, the silica thin film is utilized to form Shallow Trench Isolation (STI), Inter-Layer Dielectric (ILD), Inter-Metal Dielectric (IMD) layers, and/or the like as an insulation layer. The STI layer is utilized to appropriately or suitably separate devices such as transistors in an integrated circuit (IC), and is formed by filling a trench with an insulating material after forming the trench on a semiconductor substrate. This filled trench regulates the size and disposition of an active region. In addition, the silica thin film includes an interlayer insulating layer formed in ILD and IMD regions. In order to form these STI, ILD, and IMD insulation layers, a silica film may be formed by filling a gap in an integrated circuit (IC) and forming one layer with a silicon-based coating layer. When the silica film is formed in a semiconductor device or the like, the silica film is generally formed utilizing the following method. A hydrogenated polysiloxazane solution is spin-coated on a substrate in which a semiconductor, and if necessary, a wire, an electrode, and/or the like are formed, which has a step difference or no step difference. The coated substrate is heated to remove a solvent and subsequently baked at greater than or equal to a specific temperature to convert the hydrogenated polysiloxazane to a silica film, and this silica film is utilized as an interlayer insulating layer, a planarization layer, a passivation film, a device insulation interlayer, and/or the like. In general, a silica thin film is formed by coating a silicon (Si)-containing solution on a substrate utilizing spin coating or slit coating, and as a result, non-uniformity of the coating layer such as beads of the silicon-containing solution may be formed around (e.g., at the edges of) the substrate, or the silicon-containing solution may be applied even on the rear side of the substrate. Accordingly, a rinse solution may be utilized to strip off the silica applied in the unintentional regions, but the silica may not be removed cleanly enough to create a sharp interface, or residue (e.g., a little) silica may be left around the stripped region. A solution to this problem has been suggested, but a step difference between one region where the silica is stripped off and another region where the silica is not stripped off still needs to be improved.

### SUMMARY OF THE INVENTION

An aspect according to one embodiment of the present invention is directed toward a rinse solution for a silica thin film capable of stripping (e.g., sharply stripping) the interface region of the silica thin film.

Another aspect according to one embodiment of the present invention is directed toward a method of producing a silica thin film utilizing the rinse solution for a silica thin film.

Yet another aspect according to one embodiment of the present invention is directed toward a silica thin film produced utilizing the rinse solution for a silica thin film.

According to one embodiment, a rinse solution for a silica thin film includes trimethylbenzene, diethylbenzene, indane, indene, tert-butyl toluene, methylnaphthalene, a mixture including an aromatic hydrocarbon having 12 or more carbon atoms, a mixture including an aliphatic hydrocarbon having 12 or more carbon atoms, a mixture including a hetero hydrocarbon compound including a phenyl group and an oxygen atom, or a combination thereof.

The silica thin film may include hydrogenated polysilazane, hydrogenated polysiloxazane, or a combination thereof.

The rinse solution for a silica thin film may include a mixture including a C12 to C30 aromatic hydrocarbon, a mixture including a C12 to C30 aliphatic hydrocarbon, or a combination thereof. The mixture comprising a hetero hydrocarbon compound may comprise greater than or equal to about 10 wt % and less than or equal to about 70 wt % of the hetero hydrocarbon compound comprising a phenyl group and an oxygen atom.

The hetero hydrocarbon compound may include ether, aldehyde, alcohol, ketone, or a combination thereof in the structure.

The hetero hydrocarbon may include methylanisole, diphenylether, butylbenzoate, butylphenylether, allylmethylphenol, isobutylphenyl propionaldehyde, phenylcyclohexanone, or a combination thereof.

According to another embodiment, a method of producing a silica thin film includes coating a silicon-containing solution on a substrate; and partially spraying the rinse solution for the silica thin film on the substrate coated with the silicon-containing solution.

According to yet another embodiment, a silica thin film may be produced utilizing the rinse solution for the silica thin film.

The silica thin film may have a step difference (ΔT) of less than or equal to about 400 nm measured according to the following Equation 1.

Step difference (ΔT)=(a maximum thickness of a silica thin film measured between one side end of the silica thin film and a point 10 mm apart therefrom)−(a thickness of the silica thin film measured at a point 10 mm apart from the one side end of the silica thin film) [Equation 1]

The rinse solution for the silica thin film may strip (e.g., sharply strip) the interface region of the silica thin film without having a significant influence on its thin film characteristics by decreasing the moisture and impurities included in the rinse solution.

### BRIEF DESCRIPTION OF THE DRAWING

The drawing shows a method of evaluating stripping characteristics of a rinse solution for a silica thin film.

### DETAILED DESCRIPTION

Hereinafter, certain embodiments of the present invention will be described in more detail. However, these embodiments are examples, and do not limit the scope of the present invention, which is defined by the claims which will be described later, and equivalents thereof.

As used herein, when a definition is not otherwise provided, the term “substituted” refers to a case where instead of a hydrogen atom, a functional group is substituted with at least one substituent selected from a halogen atom (F, Cl, Br, or I), a hydroxyl group, a nitro group, a cyano group, an imino group (═NH, ═NR, R is a C1 to C10 alkyl group), an amino group (—NH₂, —NH(R′), —N(R″)(R′″), where R′ to R′″ are each independently a C1 to C10 alkyl group), an amidino group, a hydrazine or a hydrazone group, a carboxyl group, a C1 to C10 alkyl group, a C6 to C20 aryl group, a C3 to C20 cycloalkyl group, a C1 to C10 heteroalkyl group, a C3 to 20 heteroaryl group and a C2 to C20 heterocycloalkyl group; a case where instead of two hydrogen atoms, a functional group is substituted with at least one substituent selected from ═O, ═S, ═NR (R is a C1 to C10 alkyl group), ═PR (R is a C1 to C10 alkyl group) and ═SiRR′ (R and R′ are each independently a C1 to C10 alkyl group); and/or a case where instead of three hydrogen atoms, a functional group is substituted with at least one substituent selected from ≡N, ≡P and ≡SiR (R is a C1 to C10 alkyl group).

As used herein, it will be understood that when an element such as a layer, film, region, or substrate is referred to as being “on” another element, it can be directly on the other element or intervening elements may also be present.

Hereinafter, a rinse solution for a silica thin film according to one embodiment is described.

A rinse solution for a silica thin film according to one embodiment includes trimethyl benzene, diethylbenzene, indane, indene, tert-butyl toluene, methylnaphthalene, a mixture including an aromatic hydrocarbon having 12 or more carbon atoms (e.g., a mixture including two or more aromatic hydrocarbons different from one another and each having 12 or more carbon atoms, or a mixture including one aromatic hydrocarbon having 12 or more carbon atoms and another compound), a mixture including an aliphatic hydrocarbon having 12 or more carbon atoms (e.g., a mixture including two or more aliphatic hydrocarbons different from one another and each having 12 or more carbon atoms, or a mixture including one aliphatic hydrocarbon having 12 or more carbon atoms and another compound), a mixture including a hetero hydrocarbon compound including a phenyl group and an oxygen atom (e.g., two or more hetero hydrocarbon compounds different from one another and each including a phenyl group and an oxygen atom, or one hetero hydrocarbon compound and another compound), or a combination thereof.

The compound of the rinse solution for the silica thin film may have a substituted or unsubstituted structure. Here, the term “mixture” refers to a combination of two or more than two compounds, and the two or more than two compounds may be same or different.

The silica thin film may include hydrogenated polysilazane, hydrogenated polysiloxazane, or a combination thereof. For example, the silica thin film may be formed by coating a perhydropolysilazane-containing solution on a substrate and curing it.

However, a silica film formed (e.g., partially and unnecessarily formed) in places where no such film is desired during the formation of the silica thin film needs to be stripped from the substrate. The rinse solution disclosed herein has satisfactory or suitable dissolution and edge-cutting properties for the silica film, and thus, may reduce (e.g., sharply deteriorate) a step difference between one region where the silica film is stripped off and another region where the silica film is not stripped off when applied to the silica film.

The mixture including an aromatic hydrocarbon having 12 or more carbon atoms may include, for example, a C12 to C30 aromatic hydrocarbon (e.g., two or more C12 to C30 aromatic hydrocarbons), and the mixture including an aliphatic hydrocarbon having 12 or more carbon atoms may include, for example, a C12 to C30 aliphatic hydrocarbon (e.g., two or more C12 to C30 aliphatic hydrocarbons), but embodiments of the present invention are not limited thereto.

The mixture comprising a hetero hydrocarbon compound may comprise greater than or equal to about 10 wt % and less than or equal to about 70 wt % of the hetero hydrocarbon compound comprising a phenyl group and an oxygen atom.

The hetero hydrocarbon compound including a phenyl group and an oxygen atom may include a phenyl group and an oxygen-containing moiety, for example, ether, aldehyde, alcohol, ketone, or a combination thereof in the structure.

For example, the hetero hydrocarbon compound including a phenyl group and an oxygen atom may include methylanisole, diphenylether, butylbenzoate, butylphenylether, allylmethylphenol, isobutylphenyl propionaldehyde, phenylcyclohexanone, or a combination thereof, but it is not limited thereto.

The hetero hydrocarbon compound including a phenyl group and an oxygen atom may be included in an amount of greater than or equal to about 10 wt % and less than or equal to about 70 wt % based on the total amount of the rinse solution mixture (i.e., the rinse solution), in the rinse solution for a silica thin film. In this case, step difference characteristics of the silica thin film may be improved (e.g., a step difference of the silica thin film may be reduced).

According to one embodiment, the rinse solution for a silica thin film is gelated at a slow speed and thus, shows satisfactory or suitable storage-stability (e.g., shelf-life). It also reduces or minimizes an influence on thin film characteristics and strips (e.g., sharply strips) the interface of the silica thin film.

A moisture content of the rinse solution for a silica thin film may be, for example, less than or equal to about 150 ppm, and in one embodiment, less than or equal to about 100 ppm. In one embodiment, when the moisture content of the rinse solution for a silica thin film is within these ranges, the rinse solution for a silica thin film has satisfactory or suitable stripping performance without any significant influence on the thin film characteristics of the silica thin film.

According to another embodiment, a method of producing a silica thin film includes preparing a substrate; coating a silicon-containing solution on the substrate; and partially spraying the rinse solution for a silica thin film on the substrate (e.g., spraying the rinse solution for a silica thin film on only a portion of the substrate) coated with the silicon-containing solution.

The material of the substrate is not particularly limited, and may be, for example, a silicon wafer. In addition, the substrate has no particular limit in terms of its shape and may have a shape such as a plate, a film, or the like. The substrate may have various suitable surfaces such as a flat surface, a concavo-convex surface, or a curved surface, without being limited thereto.

The silicon-containing solution may include a silicon-containing compound, for example, hydrogenated polysilazane, hydrogenated polysiloxazane, or a combination thereof, and a solvent. The properties of the silicon-containing compound are not particularly limited, and may include, for example, a weight average molecular weight of about 1,000 to about 200,000, an oxygen content of about 0.2 wt % to about 3 wt %, a ratio of a SiH₃ group relative to the total SiH group (e.g., the total of SiH, SiH₂ and SiH₃ group) of 15 mol % to 35 mol %, and a chlorine content of less than or equal to about 1 ppm.

The silicon-containing solution may be coated utilizing any suitable method, for example, spin coating, spray coating, flow coating, roller coating, dip coating, wiping, sponge wiping, or the like, but embodiments of the present invention are not limited thereto.

The spraying of a rinse solution for a silica thin film may be performed in a region where a component to be removed by the rinse solution is present, for example, at the edge portion and/or on the rear side of the substrate, while the substrate coated with the silicon-containing solution is rotated at a speed of about 500 to 4,000 rpm.

According to one embodiment, a silica thin film produced utilizing the rinse solution for a silica thin film is provided. The silica thin film may be utilized for an insulation layer, a planarization layer, a passivation layer, a device insulation interlayer of a semiconductor device, a display device, and/or the like.

The silica thin film has excellent or suitable stripping characteristics on its interface (e.g., an interface between a stripped portion and a non-stripped portion) and may have, for example, less than or equal to about 400 nm of a step difference (ΔT) measured according to the following Equation 1.

Step difference (ΔT)=(a maximum thickness of a silica thin film measured between one side end (e.g., one edge) of the silica thin film and a point 10 mm apart therefrom)−(a thickness of the silica thin film measured at a point 10 mm apart from the one side end of the silica thin film) [Equation 1]

Hereinafter, the present disclosure is illustrated in more detail with reference to examples. However, these examples are for illustrative purposes only, and the present disclosure is not limited thereto.

### Synthesis Example

### Synthesis of Silicon-Containing Compound

The internal atmosphere of a reactor equipped with a 2 L agitator and a temperature controller was exchanged with dry nitrogen. 1,500 g of dry pyridine was put in the reactor, and then, the reactor was warmed at 20° C. Subsequently, 100 g of dichlorosilane was slowly injected thereinto over one hour. Next, 70 g of ammonia was slowly injected thereinto over 3 hours, while the reactor was agitated. Then, dry nitrogen was injected thereinto over 30 minutes, and ammonia remaining in the reactor was removed. The obtained white slurry-phased product was filtered through a 1 μm Teflon (PTFE) filter under a dry nitrogen atmosphere, obtaining 1,000 g of a filtered solution. Then, 1,000 g of dry xylene was added thereto, the solvent of the mixture was three times substituted from pyridine to xylene by utilizing a rotary evaporator to adjust its concentration into 20 wt %, and the concentrated product was filtered through a Teflon filter having a pore size of 0.03 μm. The obtained perhydropolysilazane has an oxygen content of 3.8%, SiH₃/SiH (total) of 0.22, a weight average molecular weight of 4,000, and a chlorine content of 0.9 ppm.

### Examples 1 to 11 and Comparative Examples 1 to 4

### Rinse Solution for Silica Thin Film

Rinse solutions for a silica thin film having the compositions in the following Table 1 were prepared.

(Evaluation 1: Evaluation of Residual Film and Step Difference Characteristics)

The compound according to the Synthesis Example was mixed with a di-n-butylether solvent to prepare a silicon-containing solution (20 wt %). 3 cc of the silicon-containing solution was set in a spin coater and coated in the center of a silicon wafer (e.g., a bare silicon wafer) having a diameter of 8 inches at a rotation speed of 1500 rpm for 20 seconds, forming an about 500 nm-thick film. Subsequently, each rinse solution for a silica thin film according to Examples 1 to 11 and Comparative Examples 1 to 4 was sprayed at a flow rate of 10 ml/min for 5 seconds from an upper place about 3 mm away from the external circumference of the wafer. Then, the coated wafer was heated and dried on a 150° C. hot plate for 3 minutes.

Stripping characteristics of the silica thin film obtained from the above process was evaluated.

The drawing shows a method of evaluating stripping characteristics of the rinse solution for a silica thin film.

Referring to the drawing, the end of the silica thin film (e.g., the portion of the silica thin film located toward the edge of the silicon wafer) is convex-shaped and produces a step difference (ΔT) with the silica thin film located toward the center of the silicon wafer. Further, a part for peeling, that is, a 3 mm wide film from the wafer external circumference region (e.g., from the edge of the wafer), was removed utilizing the rinse solution for a silica thin film to examine if there was a residual silica thin film or not.

The step difference (ΔT) was measured by utilizing an XE300 (PARK Systems) as a spectral reflection film thickness meter, and an SEM S-4800 (Type-2, Hitachi Ltd.) was utilized for scanning the area from the wafer external circumference region to about 10 mm therefrom toward the center of the wafer (the SEM was utilized for around ΔT). An optical microscope, LV100D (Nikon Inc.) and a spectral reflection film thickness meter, ST-4000 (K-MAC) were utilized to examine if there was any film residue in the part for peeling.

(Evaluation 2: Gelation Day)

2.3 g of the silicon-containing solution and 23 g of each rinse solution for a silica thin film according to Examples 1 to 11 and Comparative Examples 1 to 4 which were utilized in Evaluation 1 were put and mixed in a 100 g glass bottle and then, allowed to stand at 22° C. under 50% of RH with the bottle cap open and examined with naked eyes for the days until the mixture became gelated.

The results of Evaluations 1 to 2 are provided in the following Table 1.

TABLE 1

| | | Δ T | Film | Gelation |
|---|---|---|---|---|
| | Solvent | (nm) | residue | days |
| Example 1 | trimethyl benzene | 70 | Good | >10 |
| Example 2 | Indane | 14 | Good | >10 |
| Example 3 | Indene | 31 | Good | >10 |
| Example 4 | diethyl benzene | 65 | Good | >10 |
| Example 5 | Methylanisole | 31 | Good | 5 |
| Example 6 | tertiarybutyl toluene | 20 | Good | >10 |
| Example 7 | indane (25 w %)/ | 21 | Good | >10 |
| | ISOLEC (75 w %) | | | |
| Example 8 | diphenylether (30 wt %)/ | 30 | Good | 7 |
| | D110 (70 wt %) | | | |
| Example 9 | methylanisole (30 wt %)/ | 27 | Good | 5 |
| | D110 (70 wt %) | | | |
| Example 10 | butylbenzoate (30 wt %)/ | 60 | Good | 5 |
| | D110 (70 wt %) | | | |
| Example 11 | K600ND | 20 | Good | >10 |
| Comparative | dibutylether | 437 | Good | 1.0 |
| Example 1 | | | | |
| Comparative | hexane | 110 | film | 0.5 |
| Example 2 | | | residue | |
| | | | remains | |
| Comparative | xylene | 570 | Good | >10 |
| Example 3 | | | | |
| Comparative | decaline | 650 | Good | >10 |
| Example 4 | | | | |

* D110 (Dongsung Highchem Co., Ltd.): a mixture including an aliphatic compound having greater than or equal to 12 carbon atoms.
* ISOLEC (S-oil Corp.): a mixture including an aromatic compound having greater than or equal to 12 carbon atoms.
* K600ND (SKC Inc.): a mixture of (i) an aromatic compound having greater than or equal to 11 carbon atoms, and (ii) phenyl and an ether/aldehyde-containing compound. K600ND includes greater than or equal to about 10 wt % and less than or equal to about 70 wt % of the phenyl and an ether/aldehyde-containing compound.

Referring to Table 1, Examples utilizing the rinse solution according to one or more embodiments of the present invention showed a decreased film step difference compared with the Comparative Examples, and when cut at the external circumference region, no residual film remained. In addition, Examples utilizing the rinse solution according to one or more embodiments of the present invention showed excellent or suitable storage-stability.

The use of “may” when describing embodiments of the present invention refers to “one or more embodiments of the present invention.” Expressions such as “at least one of,” when preceding a list of elements, modify the entire list of elements and do not modify the individual elements of the list. As used herein, the term “substantially,” “about,” and similar terms are used as terms of approximation and not as terms of degree, and are intended to account for the inherent deviations in measured or calculated values that would be recognized by those of ordinary skill in the art. Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. §112, first paragraph, or 35 U.S.C. §112(a), and 35 U.S.C. §132(a).

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A rinse solution for a silica thin film, comprising trimethylbenzene, diethylbenzene, indane, indene, methylanisole, tert-butyl toluene, a mixture comprising an aromatic hydrocarbon having 12 or more carbon atoms, a mixture comprising an aliphatic hydrocarbon having 12 or more carbon atoms, a mixture comprising a hetero hydrocarbon compound comprising a phenyl group and an oxygen atom, or a combination thereof.

2. The rinse solution for the silica thin film of claim 1, wherein the silica thin film comprises hydrogenated polysilazane, hydrogenated polysiloxazane, or a combination thereof.

3. The rinse solution for the silica thin film of claim 1, wherein the rinse solution for the silica thin film comprises a mixture comprising a C12 to C30 aromatic hydrocarbon, a mixture comprising a C12 to C30 aliphatic hydrocarbon, or a combination thereof.

4. The rinse solution for the silica thin film of claim 1, wherein the mixture comprising a hetero hydrocarbon compound comprises greater than or equal to about 10 wt % and less than or equal to about 70 wt % of the hetero hydrocarbon compound comprising a phenyl group and an oxygen atom.

5. The rinse solution for the silica thin film of claim 1, wherein the hetero hydrocarbon compound comprises an ether, an aldehyde, an alcohol, a ketone, or a combination thereof in the structure.

6. The rinse solution for the silica thin film of claim 1, wherein the hetero hydrocarbon compound comprises methylanisole, diphenylether, butylbenzoate, butylphenylether, allylmethylphenol, isobutylphenyl propionaldehyde, phenylcyclohexanone, or a combination thereof.

7. A method of producing a silica thin film, the method comprising
preparing a substrate;
coating a silicon-containing solution on the substrate; and
partially spraying the rinse solution for the silica thin film of claim 1 on the substrate coated with the silicon-containing solution.

8. The method of claim 7, wherein the silica thin film comprises hydrogenated polysilazane, hydrogenated polysiloxazane, or a combination thereof.

9. The method of claim 7, wherein the rinse solution for the silica thin film comprises a mixture comprising a C12 to C30 aromatic hydrocarbon, a mixture comprising a C12 to C30 aliphatic hydrocarbon, or a combination thereof.

10. The method of claim 7, wherein the mixture comprising a hetero hydrocarbon compound comprises greater than or equal to about 10 wt % and less than or equal to about 70 wt % of the hetero hydrocarbon compound comprising a phenyl group and an oxygen atom.

11. The method of claim 7, wherein the hetero hydrocarbon compound comprises an ether, an aldehyde, an alcohol, a ketone, or a combination thereof in the structure.

12. The method of claim 7, wherein the hetero hydrocarbon compound comprises methylanisole, diphenylether, butylbenzoate, butylphenylether, allylmethylphenol, isobutylphenyl propionaldehyde, phenylcyclohexanone, or a combination thereof.

13. A silica thin film produced utilizing the rinse solution for the silica thin film of claim 1.

14. The silica thin film of claim 13, wherein the silica thin film comprises hydrogenated polysilazane, hydrogenated polysiloxazane, or a combination thereof.

15. The silica thin film of claim 13, wherein the rinse solution for the silica thin film comprises a mixture comprising a C12 to C30 aromatic hydrocarbon, a mixture comprising a C12 to C30 aliphatic hydrocarbon, or a combination thereof.

16. The silica thin film of claim 13, wherein the mixture comprising a hetero hydrocarbon compound comprises greater than or equal to about 10 wt % and less than or equal to about 70 wt % of the hetero hydrocarbon compound comprising a phenyl group and an oxygen atom.

17. The silica thin film of claim 13, wherein the hetero hydrocarbon compound comprises an ether, an aldehyde, an alcohol, a ketone, or a combination thereof in the structure.

18. The silica thin film of claim 13, wherein the hetero hydrocarbon compound comprises methylanisole, diphenylether, butylbenzoate, butylphenylether, allylmethylphenol, isobutylphenyl propionaldehyde, phenylcyclohexanone, or a combination thereof.

19. The silica thin film of claim 13, wherein the silica thin film has a step difference (ΔT) of less than or equal to about 400 nm measured according to the following Equation 1:
Step difference (ΔT)=(a maximum thickness of a silica thin film measured between one side end of the silica thin film and a point 10 mm apart therefrom)−(a thickness of the silica thin film measured at a point 10 mm apart from the one side end of the silica thin film). Equation 1
